(19) United States
(12) Patent Application Publication
(10) Pub. No.: US 2024/0413026 A1
(43) Pub. Date: Dec. 12, 2024

(54) SEMICONDUCTOR PACKAGE AND METHOD OF MANUFACTURING THE SEMICONDUCTOR PACKAGE

(71) Applicant: SAMSUNG ELECTRONICS CO., LTD., Suwon-si (KR)

(72) Inventors: Yeongbeom KO, Suwon-si (KR); Seokgeun Ahn, Suwon-si (KR); Juhyeon Oh, Suwon-si (KR); Sanghoon Lee, Suwon-si (KR); Gwangjae Jeon, Suwon-si (KR)

(73) Assignee: SAMSUNG ELECTRONICS CO., LTD., Suwon-si (KR)

(21) Appl. No.: 18/658,546

(22) Filed: May 8, 2024

(30) Foreign Application Priority Data
Jun. 7, 2023 (KR) 10-2023-0072617
Apr. 12, 2024 (KR) 10-2024-0049137

(51) Int. Cl. H01L 23/13; H01L 23/00; H01L 23/498; H01L 25/065; H10B 80/00

(52) U.S. Cl. CPC H01L 23/13; H01L 23/49816; H01L 24/08; H01L 24/32; H01L 25/0652; H01L 2224/08146; H01L 2224/08225; H01L 2224/32146; H01L 2224/32225; H01L 2924/01013; H01L 2924/01022; H01L 2924/01024; H01L 2924/01028; H01L 2924/01029; H01L 2924/01042; H01L 2924/01047; H01L 2924/0105; H01L 2924/01074; H01L 2924/01079; H01L 2924/1431; H01L 2924/1434; H01L 2924/15311; H10B 80/00

(57) ABSTRACT

A semiconductor package includes a buffer die, a plurality of core die blocks sequentially stacked on the buffer die, and a molding member on the buffer die and covering outer surfaces of the plurality of core die blocks. Each of the plurality of core die blocks includes a first semiconductor chip, a second semiconductor chip disposed on the first semiconductor chip and a first gap filling portion, a third semiconductor chip disposed on the second semiconductor chip and a second gap filling portion, and a fourth semiconductor chip disposed on the third semiconductor chip.

### CROSS-REFERENCE TO RELATED APPLICATIONS

This application claims priority under 35 U.S.C. § 119 to Korean Patent Application Nos. 10-2023-0072617, filed on Jun. 7, 2023 and 10-2024-0049137, filed on Apr. 12, 2024 in the Korean Intellectual Property Office (KIPO), the contents of which being herein incorporated by reference in its entirety.

### BACKGROUND

Example embodiments relate to a semiconductor package and a method of manufacturing the semiconductor package. More particularly, example embodiments relate to a semiconductor package including a plurality of sequentially stacked semiconductor chips and a method of manufacturing the same.

In bonding processes of stacking a plurality of semiconductor chips on one another, a chip on wafer (COW) bonding process may be used to stack a plurality of semiconductor chips on a semiconductor wafer. In the chip on wafer bonding process, the number of the semiconductor chips stacked on the semiconductor wafer may be increased in order to improve a performance of a semiconductor package. When the number of the stacked semiconductor chips is increased, a thickness of the semiconductor chip may need to be further decreased, and defects such as warpage, dishing, erosion, etc. may occur.

### SUMMARY

It is an aspect to provide a semiconductor package having a structure capable of reducing defects and increasing the number of stacked semiconductor chips.

It is another aspect to provide a method of manufacturing the semiconductor package.

According to an aspect of one or more example embodiments, there is provided a semiconductor package comprising a buffer die; a plurality of core die blocks sequentially stacked on the buffer die; and a molding member on the buffer die and covering outer surfaces of the plurality of core die blocks. Each of the plurality of core die blocks includes a first semiconductor chip having a plurality of first conductive pads that are exposed from a first upper surface of the first semiconductor chip and a plurality of first bonding pads that are exposed from a first lower surface of the first semiconductor chip; a second semiconductor chip and a first gap filling portion covering an outer side surface of the second semiconductor chip, the second semiconductor chip having a plurality of second conductive pads that are exposed from a second upper surface of the second semiconductor chip and a plurality of second bonding pads that are exposed from a second lower surface of the second semiconductor chip, the plurality of second bonding pads of the second semiconductor chip being bonded to the plurality of first conductive pads of the first semiconductor chip; a third semiconductor chip and a second gap filling portion covering an outer side surface of the third semiconductor chip, the third semiconductor chip having a plurality of third conductive pads that are exposed from a third upper surface of the third semiconductor chip and a plurality of third bonding pads that are exposed from a third lower surface of the third semiconductor chip, the plurality of third bonding pads of the third semiconductor chip being bonded to the plurality of second conductive pads of the second semiconductor chip; and a fourth semiconductor chip having a plurality of fourth bonding pads that are exposed from a fourth lower surface of the fourth semiconductor chip that is opposite to a fourth upper surface of the fourth semiconductor chip, the plurality of fourth bonding pads being bonded to the plurality of third conductive pads of the third semiconductor chip.

According to another aspect of one or more example embodiments, there is provided a semiconductor package comprising a buffer die having a first surface and a second surface opposite to the first surface, the buffer die having a plurality of substrate pads that are exposed from the first surface; and a plurality of core die blocks sequentially stacked on the first surface of the buffer die. Each of the plurality of core die blocks includes a first semiconductor chip having a plurality of first conductive pads that are exposed from a first upper surface of the first semiconductor chip and a plurality of first bonding pads that are exposed from a first lower surface of the first semiconductor chip; a second semiconductor chip and a first gap filling portion covering an outer side surface of the second semiconductor chip, the second semiconductor chip having a plurality of second conductive pads that are exposed from a second upper surface of the second semiconductor chip and a plurality of second bonding pads that are exposed from a second lower surface of the second semiconductor chip, the plurality of second bonding pads of the second semiconductor chip being bonded to the plurality of first conductive pads; a third semiconductor chip and a second gap filling portion covering an outer side surface of the third semiconductor chip, the third semiconductor chip having a plurality of third conductive pads that are exposed from a third upper surface of the third semiconductor chip and a plurality of third bonding pads that are exposed from a third lower surface of the third semiconductor chip, the plurality of third bonding pads of the third semiconductor chip being bonded to the plurality of second conductive pads of the second semiconductor chip; and a fourth semiconductor chip having a plurality of fourth conductive pads that are exposed from a fourth upper surface of the fourth semiconductor chip and a plurality of fourth bonding pads that are exposed from a fourth lower surface of the fourth semiconductor chip, the plurality of fourth bonding pads being bonded to the plurality of third conductive pads of the third semiconductor chip, and the plurality of first bonding pads of a lowermost core die block among the plurality of core die blocks are bonded to the plurality of substrate pads of the buffer die.

According to yet another aspect of one or more example embodiments, there is provided a semiconductor package comprising a buffer die having a first surface and a second surface opposite to the first surface; a plurality of core die blocks sequentially stacked on the first surface of the buffer die; and a molding member on the first surface of the buffer die covering outer surfaces of the plurality of the core die blocks. Each of the core die blocks includes a first semiconductor chip having a first upper surface and a first lower surface opposite to the first upper surface, the first semiconductor chip having a plurality of first conductive pads that are exposed from the first upper surface and a plurality of first bonding pads that are exposed from the first lower surface; a second semiconductor chip and a first gap filling portion covering an outer side surface of the second semiconductor chip, the second semiconductor chip having a second upper surface and second lower surface opposite to the second upper surface, a plurality of second conductive pads that are exposed from the second upper surface and a plurality of second bonding pads that are exposed from the second lower surface, the plurality of second bonding pads of the second semiconductor chip being bonded to the plurality of first conductive pads; a third semiconductor chip and a second gap filling portion covering an outer side surface of the third semiconductor chip, the third semiconductor chip having a third upper surface and a third lower surface opposite to the third upper surface, a plurality of third conductive pads that are exposed from the third upper surface and a plurality of third bonding pads that are exposed from the third lower surface, the plurality of third bonding pads of the third semiconductor chip being bonded to the plurality of second conductive pads of the second semiconductor chip; and a fourth semiconductor chip having a fourth upper surface and a fourth lower surface opposite to the fourth upper surface, the fourth semiconductor chip having a plurality of fourth conductive pads that are exposed from the fourth upper surface and a plurality of fourth bonding pads that are exposed from the fourth lower surface, the plurality of fourth bonding pads being bonded to the plurality of third conductive pads of the third semiconductor chip.

According to yet another aspect of one or more example embodiments, there is provided a semiconductor package comprising a buffer die, and a plurality of core die blocks sequentially stacked on the buffer die. Each of the core die blocks includes a first semiconductor chip having a plurality of first conductive pads that are exposed from a first upper surface and a plurality of first bonding pads that are exposed from a first lower surface, a second semiconductor chip and a first gap filling portion covering an outer side surface of the second semiconductor chip, the second semiconductor chip having a plurality of second conductive pads that are exposed from a second upper surface and a plurality of second bonding pads that are exposed from a second lower surface, the second semiconductor chip disposed on the first semiconductor chip such that the second bonding pads are bonded to the first conductive pads, a third semiconductor chip and a second gap filling portion covering an outer side surface of the third semiconductor chip, the third semiconductor chip having a plurality of third conductive pads that are exposed from a third upper surface and a plurality of third bonding pads that are exposed from a third lower surface, the third semiconductor chip disposed on the second semiconductor chips such that the third bonding pads are bonded to the second conductive pads, and a fourth semiconductor chip having a plurality of fourth bonding pads that are exposed from a fourth lower surface opposite to a fourth upper surface, the fourth semiconductor chip disposed on the third semiconductor chip such that the fourth bonding pads are bonded to the third conductive pads.

### BRIEF DESCRIPTION OF THE DRAWINGS

Example embodiments will be more clearly understood from the following detailed description taken in conjunction with the accompanying drawings, in which FIGS. 1 to 22 represent non-limiting, example embodiments and in which:

FIG. 1 is a cross-sectional view illustrating a semiconductor package in accordance with some example embodiments;

FIG. 2 is a cross-sectional view illustrating a core die block in the semiconductor package of FIG. 1, according with some example embodiments;

FIGS. 3 to 19 are cross-sectional views illustrating a method of manufacturing a semiconductor package in accordance with some example embodiments;

FIG. 20 is a cross-sectional view illustrating a semiconductor package in accordance with some example embodiments; and

FIGS. 21 and 22 are cross-sectional views illustrating a method of manufacturing a semiconductor package in accordance with example embodiments.

### DETAILED DESCRIPTION

According to various example embodiments, a core die block may be disposed on the buffer die. A first semiconductor chip, a second semiconductor chip and a first gap filling portion may constitute a first sub-block. A third semiconductor chip, a fourth semiconductor chip and a second gap filling portion may constitute a second sub-block. The first and second sub-blocks may constitute the core die block. Since the second semiconductor chip and the third semiconductor chip are provided to support and bond between the first semiconductor chip and the fourth semiconductor chip, the core die block may have high structural stability as a single semiconductor module. When a plurality of the core die blocks are stacked on the buffer die, the structural stability of the semiconductor package may be increased.

In some example embodiments, since a gap filling portion is formed between the first semiconductor chip and the fourth semiconductor chip to cover the second semiconductor chip and the third semiconductor chip, adhesion defects between semiconductor chips that occur when a plurality of semiconductor chips having the same area are stacked may be prevented.

In a process of manufacturing the semiconductor package according to various example embodiments, the plurality of second semiconductor chips are disposed on a first wafer including the first semiconductor chips to form a first sub-package, and the plurality of third semiconductor chips are disposed on a second wafer including the fourth semiconductor chips to form a second sub-package. The first and second sub-packages may be bonded to each other to form the core die block.

In some example embodiments, since the first and second sub-packages are respectively formed by separate processes, the number of chip mounting times may be reduced compared to a case where a plurality of chips are individually stacked on the buffer die. Since the number of chip mounting times is reduced, chip alignment problems may be reduced. Since the first and second sub-packages are respectively formed, a warpage phenomenon occurring in a process of arranging thin chips may be prevented. Since a polishing process may be performed in the process of forming the first and second sub-packages, occurrence of a dishing phenomenon or an erosion phenomenon occurring in the core die block may be reduced.

Hereinafter, various example embodiments will be explained in detail with reference to the accompanying drawings.

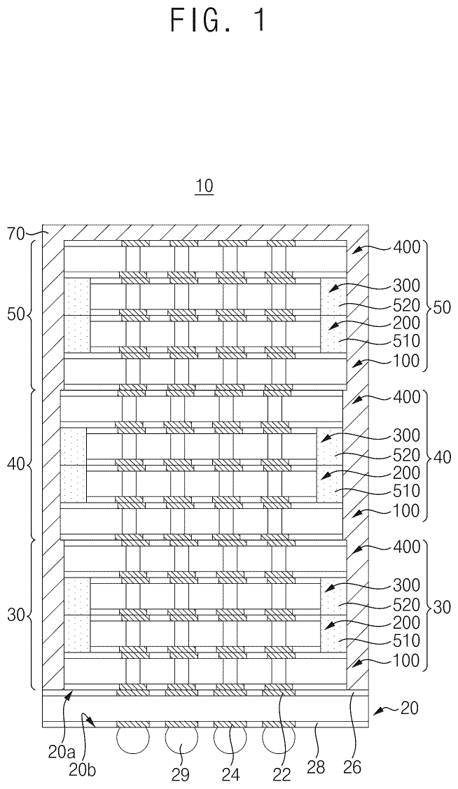

FIG. 1 is a cross-sectional view illustrating a semiconductor package in accordance with example embodiments.

Referring to FIG. 1, a semiconductor package 10 may include a buffer die 20, and a plurality of core die blocks stacked on the buffer die 20. The plurality of core die blocks may include a first core die block 30, a second core die block 40, and a third core die block 50. Additionally, the semiconductor package 10 may further include a molding member 70 that covers outer side surfaces of the plurality of core die blocks 30, 40, and 50.

The plurality of core die blocks 30, 40, and 50 may be vertically stacked on the buffer die 20. In the embodiment illustrated in FIG. 1, the first to third core die blocks 30, 40, and 50 may be substantially the same as or similar to each other. Thus, same or like reference numerals will be used to refer to the same or like elements and repeated descriptions of the same elements may be omitted for conciseness.

The buffer die 20 may be a chip that has a first surface 20a and a second surface 20b opposite to the first surface 20a. The buffer die 20 may include first substrate pads 22, second substrate pads 24, a first substrate insulating layer 26 that exposes the first substrate pads 22, and a second substrate insulating layer 28 exposes the second substrate pads 24. The first substrate pads 22 may be provided on the first surface 20a of the buffer die 20, and the second substrate pads 24 may be provided on the second surface 20b.

The first core die block (i.e., a lowermost core die block) 30 may be directly disposed on the buffer die 20. The first to third core die blocks 30, 40, and 50 may be sequentially stacked on the buffer die 20. The third core die block 50 may be an uppermost core die block. External connection bumps 29 may be provided on the second substrate pads 24 to electrically connect the buffer die 20 to other semiconductor devices.

In the embodiment illustrated in FIG. 1, the semiconductor package as a multi-chip package is illustrated as including the buffer die 20 and the three stacked core die blocks 30, 40, and 50. However, embodiments are not limited thereto, and for example, in some embodiments, the semiconductor package may include four, five, six, seven or more stacked semiconductor devices.

Each of the first to third core die blocks 30, 40, and 50 may include integrated circuit chips (indicated by shaded regions in FIG. 1) that are completed by performing semiconductor manufacturing processes. For example, each of the core die blocks may include a memory chip or a logic chip. The semiconductor package 10 may include a memory device. The memory device may include a high bandwidth memory (HBM) device.

Hereinafter, the first, second and third core die blocks 30, 40, and 50 will be described.

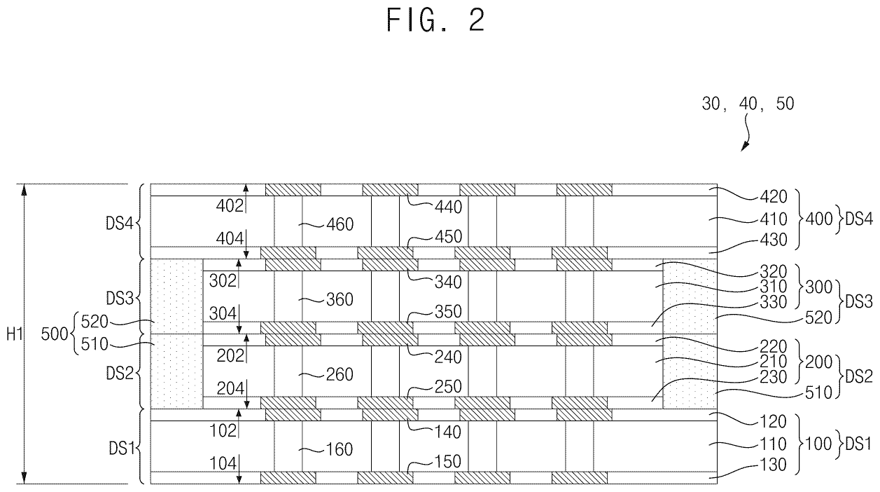

FIG. 2 is a cross-sectional view illustrating the core die block in FIG. 1, according with some example embodiments.

Referring to FIGS. 1 and 2, each of the core die blocks 30 may include first, second, third and fourth die structures DS1, DS2, DS3, and DS4 sequentially stacked. The first die structure DS1 may include a first semiconductor chip 100. The second die structure DS2 may include a second semiconductor chip 200 and a first gap filling portion 510 that covers an outer side surface of the second semiconductor chip 200. The third die structure DS3 may include a third semiconductor chip 300 and a second gap filling portion 520 that covers an outer side surface of the third semiconductor chip 300. The fourth die structure DS4 may include a fourth semiconductor chip 400.

The first, second, and third core die blocks 30, 40, and 50 may be substantially the same as or similar to each other. Each of the first, second, and third core die blocks 30, 40, and 50 may have a rectangular parallelepiped shape. A lower surface of the first die structure DS1 may serve as a lower surface of each core die block, and an upper surface of the fourth die structure DS4 may serve as an upper surface of each core die block.

The first core die block 30 may include a first sub-block and a second sub-block. The first sub-block may include the first semiconductor chip 100, the second semiconductor chip 200, and the first gap filling portion 510 surrounding the second semiconductor chip 200. The second sub-block may include the third semiconductor chips 300, the fourth semiconductor chip 400, and the second gap filling portion 520 surrounding the third semiconductor chip 300.

The first semiconductor chip 100 of the first core die block 300 may be disposed on and in contact with the buffer die 20. The first semiconductor chip 100 may include a first upper surface 102 and a first lower surface 104 opposite to the first upper surface 102. The first lower surface 104 of the first semiconductor chip 100 may face the buffer die 20, and may be provided on the buffer die 20 (see FIG. 1).

The second to fourth semiconductor chips 200, 300, and 400 may be vertically stacked on the first semiconductor chip 100. In the embodiment illustrated in FIG. 2, the first to fourth semiconductor chips 100, 200, 300, and 400 may be substantially the same as or similar to each other. Thus, same or similar elements are denoted by the same or similar reference numerals, and repeated descriptions of the same components will be omitted for conciseness.

In example embodiments, the first semiconductor chip 100 of the first die structure DS1 may include a first substrate 110, a first upper insulating layer 120 provided on an upper surface of the first substrate 110, a first lower insulating layer 130 provided to cover a first circuit layer that is provided on a lower surface of the first substrate 110, a plurality of first conductive pads 140 provided in the first upper insulating layer 120, a plurality of first bonding pads 150 provided in the first lower insulating layer 130, and a plurality of first through electrodes 160 electrically connected to the first circuit layer and extending between the first bonding pads 150 and the first conductive pads 140.

The first lower surface 104 of the first semiconductor chip 100 of the first core die block 30 may face the first surface 20a of the buffer die 20. The first lower insulating layer 130 of the first semiconductor chip 100 and the first substrate insulating layer 26 of the buffer die 20 may be directly bonded to each other. Thus, the first substrate pads 22 and the first bonding pads 150 may be mutually connected between the buffer die 20 and the first semiconductor chip 100 by copper-to-copper (Cu—Cu) Hybrid Bonding. For example, pad to pad direct bonding may be formed.

In example embodiments, the first substrate 110 may have an active surface and an inactive surface opposite to the active surface. An activation layer may be provided on the active surface of the first substrate 110. Circuit patterns may be provided in the activation layer of the first substrate 110. For example, the first substrate 110 may include a semiconductor material such as silicon, germanium, or silicon-germanium. The first substrate 110 may include III-V compounds such as gallium phosphide (GaP), gallium arsenide (GaAs), or gallium antimonide (GaSb).

The circuit patterns may include transistors, diodes, etc. The circuit patterns may constitute circuit elements. Accordingly, the first semiconductor chip 100 may include a plurality of circuit elements therein. The circuit pattern may be formed by a wafer process called a front-end-of-line (FEOL) process.

A wiring layer may be provided on one surface of the first substrate 110. The wiring layer may be formed on the one surface of the first substrate 110 by a wiring process that is called a back-end-of-line process. The wiring layer may include wires therein. For example, the wires may include aluminum (Al), copper (Cu), tin (Sn), nickel (Ni), gold (Au), or platinum (Pt), or an alloy thereof.

In example embodiments, the first through electrode 160 may be electrically connected to the first circuit layer. The first through electrode 160 may extend to penetrate the first substrate 110.

The first through electrode 160 may vertically penetrate the first substrate 110, and may be electrically connected to the first bonding pad 150. The first through electrode 160 may be electrically connected to the first conductive pad 140. Thus, the first bonding pad 150 and the first conductive pad 140 may be electrically connected to each other by the first through electrode 160.

The first through electrodes 160, the first bonding pads 150 and the first conductive pads 140 may include a same metal. For example, the metal may include copper (Cu). However, embodiments are not limited thereto, and may the metal may include a material (e.g., gold (Au)) that can be bonded by inter-diffusion of metals by a high-temperature annealing process.

In example embodiments, the first upper insulating layer 120 may be provided on the upper surface of the first substrate 110. The first upper insulating layer 120 may cover at least a portion of an outer surface of the first conductive pad 140. The first upper insulating layer 120 may be provided on the first upper surface 102 of the first semiconductor chip 100. The first upper insulating layer 120 may be formed on a front surface of the first substrate 110 as an interlayer insulating layer.

In example embodiments, the first lower insulating layer 130 may be provided on the first lower surface 104 of the first semiconductor chip 100. The first lower insulating layer 130 may be formed on a backside surface opposite to the front surface of the first substrate 110. The first bonding pad 150 may be provided on the first lower insulating layer 130. The first lower insulating layer 130 may include silicon oxide, carbon-doped silicon oxide, silicon carbonitride (SiCN), or the like.

In example embodiments, the first conductive pads 140 may be exposed from the first upper surface 102 of the first semiconductor chip 100. The first conductive pads 140 may be exposed from the first upper surface 102 of the first semiconductor chip 100 and bonded to second bonding pads 250 (described below) of the second semiconductor chips 200. The first conductive pads 140 may electrically connect the first and second semiconductor chips 100 and 200 to each other.

In example embodiments, the first bonding pads 150 may be exposed from the first lower surface 104 of the first semiconductor chip 100. The first bonding pads 150 may be provided in the first lower insulating layer 130. The first bonding pads 150 may be exposed from the first lower surface 104 of the first semiconductor chip 100 and bonded to the first substrate pads 22 of the buffer die 20. The first bonding pads 150 may electrically connect the first semiconductor chip 100 and the buffer die 20 to each other.

For example, the first conductive pads 140 and the first bonding pads 150 may include nickel (Ni), antimony (Sb), bismuth (Bi), zinc (Zn), indium (In), palladium (Pd), platinum (Pt), aluminum (Al), copper (Cu), molybdenum (Mo), titanium (Ti), gold (Au), silver (Ag), chromium (Cr), or tin (Sn), or an alloy thereof.

In example embodiments, the second semiconductor chip 200 of the second die structure DS2 may be disposed on the first semiconductor chip 100 of the first die structure DS1. The second semiconductor chip 200 may be disposed on the first upper surface 102 of the first semiconductor chip 100. The second semiconductor chip 200 may have a second upper surface 202 and a second lower surface 204 opposite to the second upper surface 202. The second lower surface 204 of the second semiconductor chip 200 may be bonded to the first upper surface 102 of the first semiconductor chip 100.

A second planar area of the second semiconductor chip 200 may be smaller than a first planar area of the first semiconductor chip 100. In some embodiments, a second planar area of the second semiconductor chip 200 may be smaller than the first planar area of the first semiconductor chip 100.

In example embodiments, the second semiconductor chip 200 of the second die structure DS2 may include a second substrate 210, a second upper insulating layer 220 provided on an upper surface of the second substrate 210, a second lower insulating layer 230 configured to cover a second circuit layer provided on a lower surface of the second substrate 210, a plurality of second conductive pads 240 provided in the second upper insulating layer 220, a plurality of second bonding pads 250 provided in the second lower insulating layer 230, and a plurality of second through electrodes 260 electrically connected to the second circuit layer and extending between the second bonding pads 250 and the second conductive pads 240.

The second lower insulating layer 230 of the second semiconductor chip 200 and the first upper insulating layer 120 of the first semiconductor chip 100 may be directly bonded to each other. The second bonding pads 250 of the second semiconductor chip 200 may be bonded to the first conductive pads 140 of the first semiconductor chip 100. Thus, the first conductive pads 140 and the second bonding pads 250 may be connected to each other between the first semiconductor chip 100 and the second semiconductor chip 200 by Cu—Cu Hybrid Bonding. For example, pad to pad direct bonding may be formed.

The first gap filling portion 510 of the second die structure DS2 may cover the entire outer side surface of the second semiconductor chip 200. The first gap filling portion 510 of the second die structure DS2 may cover outer side surfaces of the second substrate 210, the second upper insulating layer 220, and the second lower insulating layer 230 of the second semiconductor chip 200. In this case, an outer side surface of the first gap filling portion 510 of the second die structure DS2 may be located on the same plane as an outer side surface of the first semiconductor chip 100 of the first die structure DS1.

In example embodiments, the third semiconductor chip 300 of the third die structure DS3 may be disposed on the second semiconductor chip 200 of the second die structure DS2. The third semiconductor chip 300 may be disposed on the second upper surface 202 of the second semiconductor chip 200. The third semiconductor chip 300 may have a third upper surface 302 and a third lower surface 304 opposite to the third upper surface 302. The third lower surface 304 of the third semiconductor chip 300 may be bonded to the second upper surface 202 of the second semiconductor chip 200. The second gap filling portion 520 of the third die structure DS3 may be disposed on the first gap filling portion 510 of the second die structure DS2. The first gap filling portion 510 and the second gap filling portion 520 may be bonded to each other to form a gap fill portion 500.

A third planar area of the third semiconductor chip 300 may be within a similar range to the second planar area of the second semiconductor chip 200. In some embodiments, a third planar area of the third semiconductor chip 300 may be within a similar range as the second planar area of the second semiconductor chip 200. The third planar area of the third semiconductor chip 300 may be smaller than the first planar area of the first semiconductor chip 100. In some embodiments, a third planar area of the third semiconductor chip 300 may be smaller than the first planar area of the first semiconductor chip 100. When viewed from a plan view, the third semiconductor chip 300 may be disposed within the first planar area of the first semiconductor chip 100.

In example embodiments, the third semiconductor chip 300 may include a third substrate 310, a third upper insulating layer 320 provided on an upper surface of the third substrate 310, a third lower insulating layer 330 configured to cover a third circuit layer provided on a lower surface of the third substrate 310, a plurality of third conductive pads 340 provided in the third upper insulating layer 320, a plurality of third bonding pads 350 provided in the third lower insulating layer 330, and a plurality of third through electrodes 360 electrically connected to the third circuit layer and extending between the third bonding pads 350 and the third conductive pads 340.

The third lower insulating layer 330 of the third semiconductor chip 300 and the second upper insulating layer 220 of the second semiconductor chip 200 may be directly bonded to each other. The third bonding pads 350 of the third semiconductor chip 300 may be bonded to the second conductive pads 240 of the second semiconductor chip 200. Thus, the second conductive pads 240 and the third bonding pads 350 may be connected to each other between the second semiconductor chips 200 and the third semiconductor chips 300 by Cu—Cu Hybrid Bonding. For example, pad to pad direct bonding may be formed.

The second gap filling portion 520 of the third die structure DS3 may cover the entire outer side surface of the third semiconductor chip 300. The second gap filling portion 520 of the third die structure DS3 may cover outer side surfaces of the third substrate 310, the third upper insulating layer 320, and the third lower insulating layer 330 of the third semiconductor chip 300. In this case, an outer side surface of the second gap filling portion 520 of the third die structure DS2 may be located on the same plane as the outer side surface of the first gap filing portion 510 and an outer side surface of the first semiconductor chip 100 of the first die structure DS1. In example embodiments, the fourth semiconductor chip 400 of the fourth die structure DS4 may be disposed on the third semiconductor chip 300 of the third die structure DS3. The fourth semiconductor chip 400 may be disposed on the third upper surface 302 of the third semiconductor chip 300. The fourth semiconductor chip 400 may have a fourth upper surface 402 and a fourth lower surface 404 opposite to the fourth upper surface 402. The fourth lower surface 404 of the fourth semiconductor chip 400 may be bonded to the third upper surfaces 302 of the third semiconductor chips 300.

In example embodiments, the fourth semiconductor chip 400 may include a fourth substrate 410, a fourth upper insulating layer 420 provided on an upper surface of the fourth substrate 410, a fourth lower insulating layer 430 configured to cover a fourth circuit layer provided on a lower surface of the fourth substrate 410, a plurality of fourth conductive pads 440 provided in the fourth upper insulating layer 420, a plurality of fourth bonding pads 450 provided in the fourth lower insulating film 430, and a plurality of fourth through electrodes 460 electrically connected to the fourth circuit layer and extending between the fourth bonding pads 450 and the fourth conductive pads 440.

The fourth lower insulating layer 430 of the fourth semiconductor chip 400 and the third upper insulating layer 320 of the third semiconductor chip 300 may be directly bonded to each other. The fourth bonding pads 450 of the fourth semiconductor chip 400 may be bonded to the third conductive pads 340 of the third semiconductor chip 300. Thus, the third conductive pads 340 and the fourth bonding pads 450 may be connected to each other between the third semiconductor chips 300 and the fourth semiconductor chip 400 by Cu—Cu Hybrid Bonding. For example, pad to pad direct bonding may be formed.

A distance from the first lower surface 104 of the first semiconductor chip 100 to the fourth upper surface 402 of the fourth semiconductor chip 400 may have a first height H1. The first height H1 may be a height of the first core die block 30. The first core die block 30 may include the first to fourth semiconductor chips 100, 200, 300, and 400 within a range of the first height H1. The first core die block 30 may stably include the first to fourth semiconductor chips 100, 200, 300, and 400 on the buffer die 20 within the range of the first height H1. For example, in some embodiments, the first height H1 may be within a range of 100 μm to 200 μm.

In example embodiments, the gap filling portion 500 may be provided between the first semiconductor chip 100 and the fourth semiconductor chip 400. The gap filling portion 500 may fill up the space between the first semiconductor chip 100 and the fourth semiconductor chip 400. The gap filling portion 500 may be provided to cover the outer side surfaces of the second semiconductor chip 200 and the third semiconductor chip 300 between the first semiconductor chip 100 and the fourth semiconductor chip 400.

Since the second and third planar areas of the second and third semiconductor chips 200 and 300 are smaller than the first planar area of the first semiconductor chip 100 as described above, the gap filling portion 500 may cover the outer side surfaces of the second and third semiconductor chips 200 and 300. A portion of the outer side surfaces may be outer surfaces of the second and third semiconductor chips 200 and 300. Since the gap filling portion 500 is configured to cover an outer surface of each of the second and third semiconductor chips 200 and 300, adhesion defects may be prevented from occurring between the plurality of semiconductor chips.

The gap filling portion 500 may include an underfill resin such as an epoxy resin, and may include a silica filler or flux. The gap filling portion 500 may include a polymer such as resin. For example, the gap filling portion 500 may include EMC (Epoxy Molding Compound). The gap filling portion 500 may include a different material or the same material as an underfill material layer. Alternatively, the gap filling portion 510 may include an inorganic dielectric layer or an organic dielectric layer. The inorganic dielectric layer may include silicon oxide, silicon oxynitride, phosphosilicate glass (PSG), boro-phosphosilicate glass (BPSG), etc. The organic dielectric layer may include a polymer or the like.

In example embodiments, the second core die block 40 may be disposed on the first core die block 30. The second core die block 40 may be disposed on the fourth semiconductor chip 400 of the first core die block 30. The second core die block 40 may be electrically connected to the fourth conductive pads 440 of the fourth semiconductor chip 400 of the first core die block 30. The second core die block 40 and the fourth upper insulating layer 420 of the fourth semiconductor chip 400 of the first core die block 30 may be directly bonded to each other. The second core die block 40 may be bonded to the fourth conductive pads 440 of the fourth semiconductor chip 400 of the first core die block 30.

In example embodiments, the molding member 70 may be provided on the buffer die 20 to cover the outer side surfaces of the first, second, and third core die blocks 30, 40, and 50.

For example, the molding member 70 may cover an upper surface of the third core die block 50. The molding member 70 may be in direct contact with the outer side surfaces of the first, second, and third core die blocks 30, 40, and 50. For example, the molding member may include a thermosetting resin. The molding material may include an epoxy mold compound (EMC). The molding material may include UV resin, polyurethane resin, silicone resin, silica filler, etc.

As mentioned above, the plurality of core die blocks 30, 40 and 50 may be stacked on the buffer die 20. The first semiconductor chip 100, the second semiconductor chip 200 and the first gap filling portion 510 surrounding the second semiconductor chip 200 of the first core die block 30 may constitute the first sub-block of the first core die block 30. The third semiconductor chip 300, the fourth semiconductor chip 400 and the second gap filling portion 520 of the first core die block 30 may constitute the second sub-block of the first core die block 30. The first and second sub-bocks may constitute the first core die block 30.

Since the second semiconductor chip 200 and the third semiconductor chip 300 are provided to support and bond between the first semiconductor chip 100 and the fourth semiconductor chip 400, the first core die block 30 may have high structural stability as a single semiconductor module. When the first to third core die blocks 30, 40, and 50 are stacked on the buffer die 20, the structural stability of the semiconductor package 10 may be increased.

Since the gap filling portion 500 is provided between the first semiconductor chip 100 and the fourth semiconductor chip 400 to cover the outer side surfaces of the second semiconductor chip 200 and the third semiconductor chip 300, adhesion defects between semiconductor chips that occur when a plurality of semiconductor chips having the same area are simply stacked may be prevented.

Hereinafter, a method of manufacturing the semiconductor package in FIG. 1 will be described.

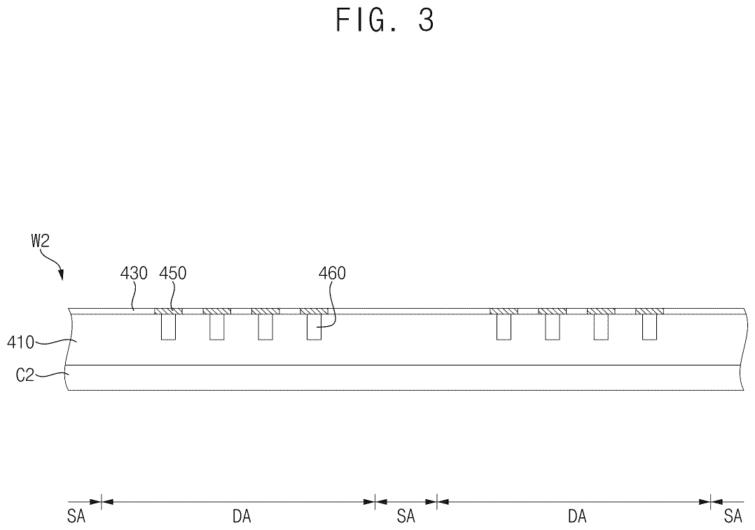

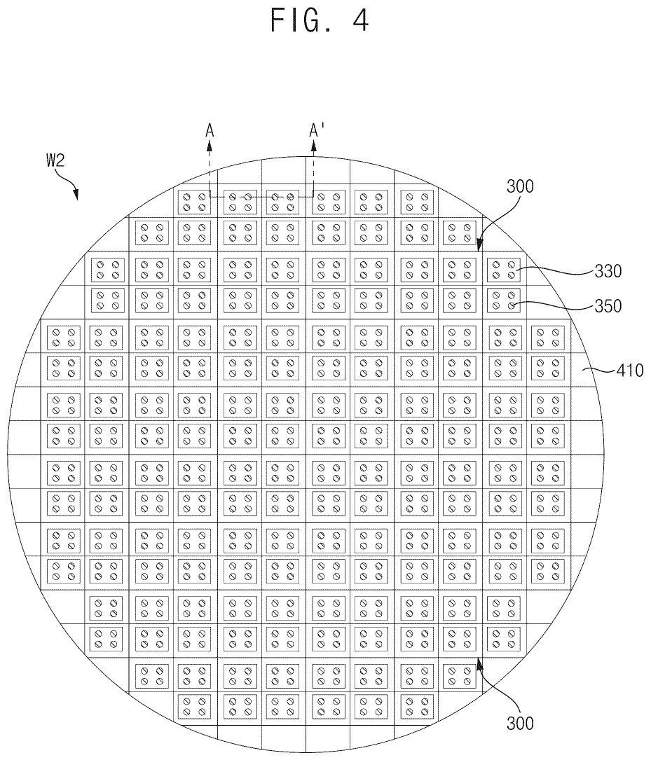

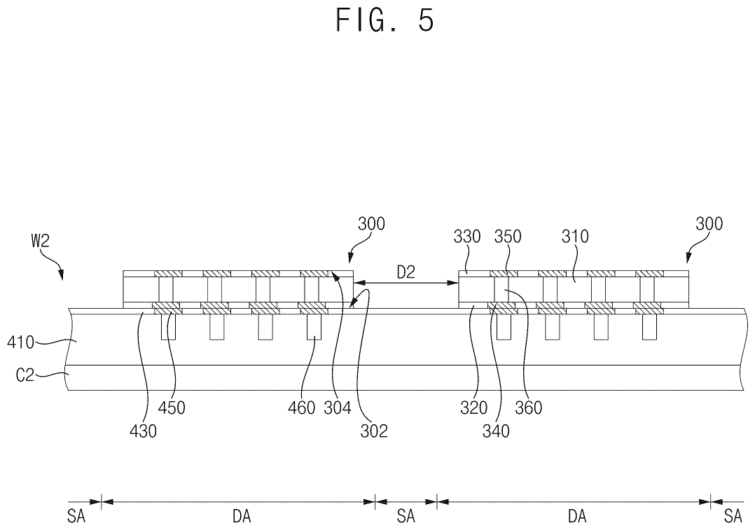

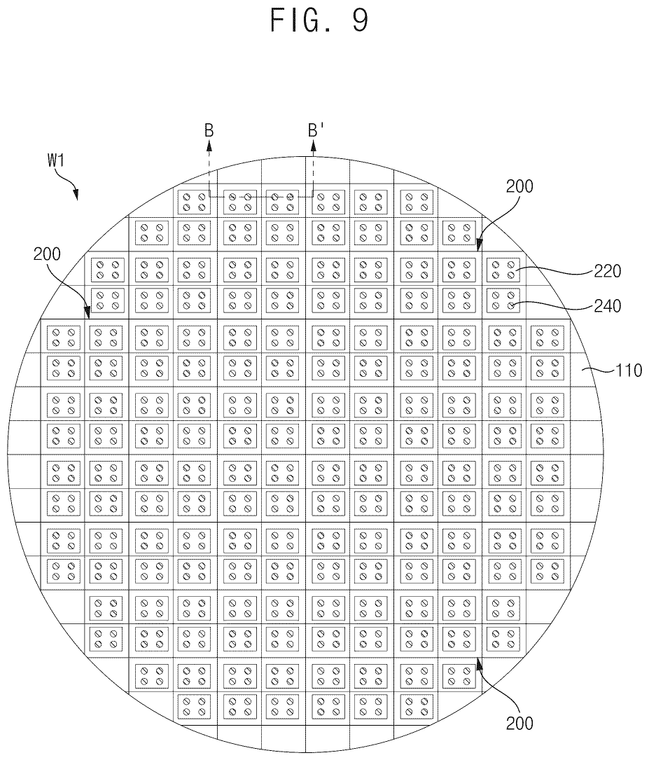

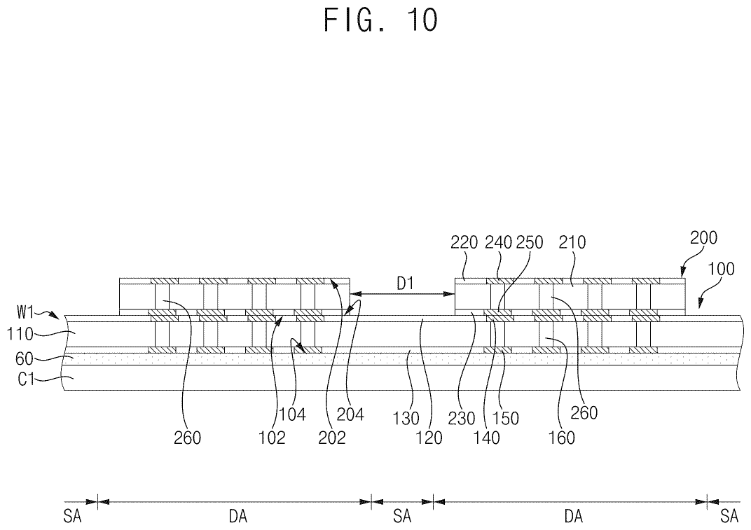

FIGS. 3 to 19 are cross-sectional views illustrating a method of manufacturing a semiconductor package in accordance with example embodiments. FIG. 5 is a cross-sectional view taken along the line A-A′ in FIG. 4. FIG. 10 is a cross-sectional view taken along the line B-B′ in FIG. 9.

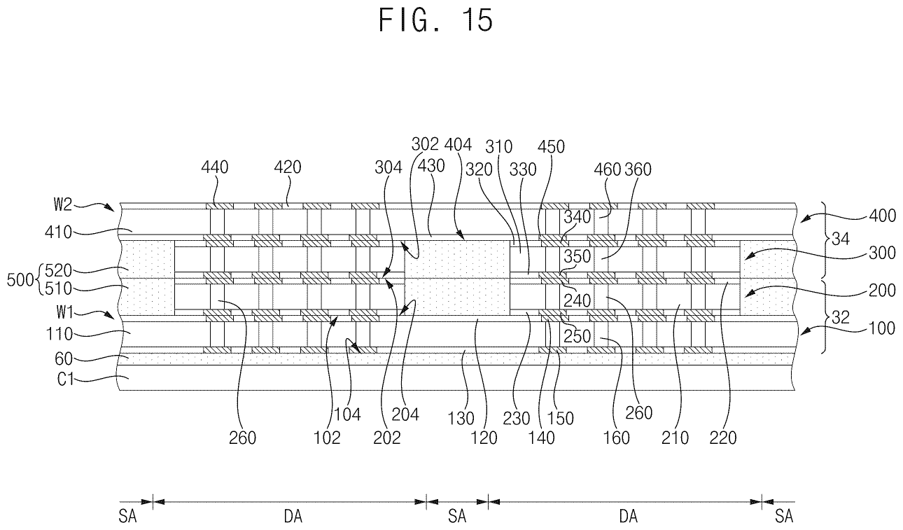

Referring to FIGS. 3 to 7, first, a second semiconductor wafer W2 may be provided, and a plurality of third semiconductor chips 300 may be disposed on the second semiconductor wafer W2. The second semiconductor wafer W2 may be a base wafer for forming a second sub-package 34 (see FIG. 15).

As illustrated in FIG. 3, the second semiconductor wafer W2 having a fourth substrate 410 may be disposed on a second carrier substrate C2. A plurality of fourth through electrodes 460 may be formed to penetrate at least a portion of the fourth substrate 410, and a fourth activation layer may be formed to be electrically connected to the fourth through electrodes 460. The fourth activation layer may have a fourth lower insulating layer 430 and fourth bonding pads 450 provided in the fourth lower insulating layer 430. The fourth bonding pads 450 may be formed to be exposed from the fourth lower insulating layer 430.

The second semiconductor wafer W2 may include a die region DA in which the fourth semiconductor chip is disposed and a cutting region SA surrounding the die region DA. As will be described later, the second semiconductor wafer W2 may be cut along the cutting region SA through a sawing process to be individualized.

As illustrated in FIGS. 4 and 5, a plurality of third semiconductor chips 300 may be disposed on the fourth activation layer of the second semiconductor wafer W2 (die-to-wafer hybrid bonding process). The third semiconductor chips 300 may be disposed on the fourth semiconductor chip 400 such that third conductive pads 340 formed in a third upper insulating layer 320 of the third semiconductor chip 300 face the fourth substrate 410. The third semiconductor chips 300 may be disposed on the fourth substrate 410 such that third upper surfaces 302 of the third semiconductor chips 300 face the fourth substrate 410. The plurality of third semiconductor chips 300 may be disposed on the fourth substrate 410 by a reconstruction method.

The plurality of third semiconductor chips 300 may be fixed on the second semiconductor wafer W2 by a thermal compression process. The thermal compression process may be referred to as a technical process of stably bonding the plurality of third semiconductor chips 300 onto the second semiconductor wafer W2 using a high-temperature heat source.

The third upper insulating layer 320 of the third semiconductor chips 300 and the fourth lower insulating layer 430 of the second semiconductor wafer W2 may be directly bonded to each other. The third conductive pads 340 of the third semiconductor chips 300 may be bonded to the fourth bonding pads 450 of the second semiconductor wafer W2. Accordingly, the third conductive pads 340 and the fourth bonding pads 450 may be connected to each other between the third semiconductor chips 300 and the second semiconductor wafer W2 by Cu—Cu hybrid bonding. For example, pad to pad direct bonding may be formed.

The plurality of third semiconductor chips 300 may be disposed to be spaced apart from each other on the fourth substrate 410. The plurality of third semiconductor chips 300 may be arranged to be spaced apart from each other by a second distance D2.

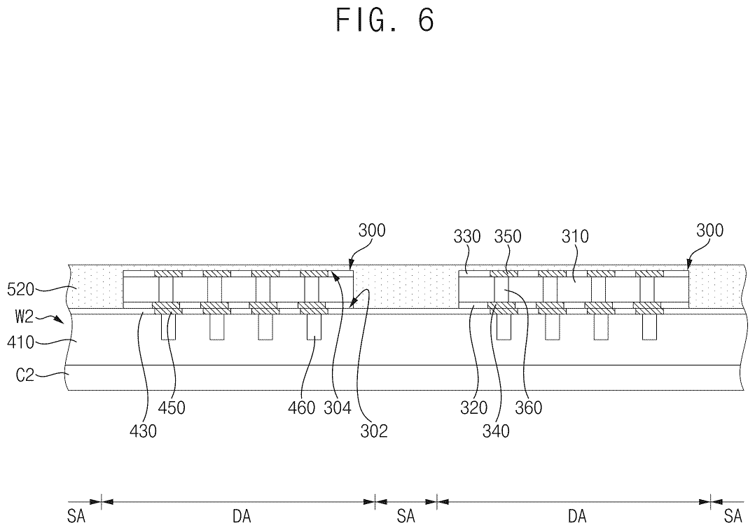

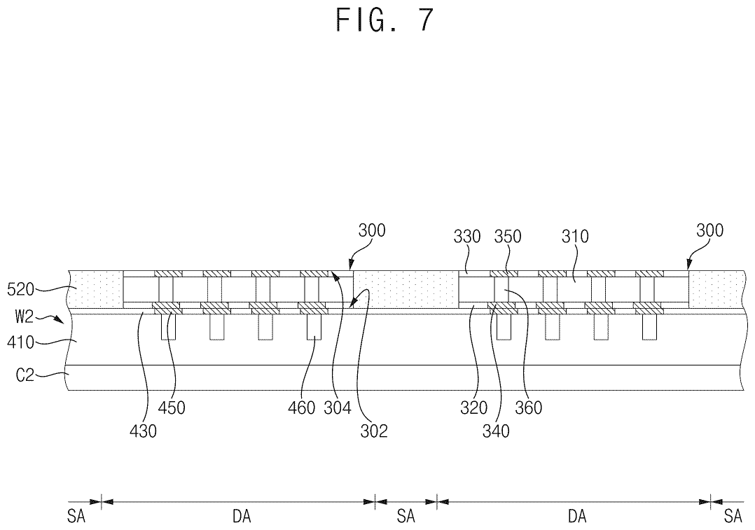

As illustrated in FIGS. 6 and 7, a second gap filling portion 520 may be formed on the second semiconductor wafer W2 to cover the plurality of third semiconductor chips 300.

In example embodiments, the second gap filling portion 520 may be formed on the second semiconductor wafer W2 to cover the plurality of third semiconductor chips 300. For example, the second gap filling portion 520 may include an epoxy molding compound (EMC) or the like. Alternatively, the second gap filling portion 520 may include an inorganic dielectric layer or an organic dielectric layer. The inorganic dielectric layer may include silicon oxide, silicon oxynitride, phosphosilicate glass (PSG), boro-phosphosilicate glass (BPSG), etc. The organic dielectric layer may include a polymer or the like. The second gap filling portion 520 may be formed by a conformal deposition process such as an atomic layer deposition (ALD) process or a chemical vapor deposition (CVD) process.

Then, the second gap filling portion 520 may be polished using a substrate support system (WSS). The second gap filling portion 520 may be partially removed until the third bonding pads 350 formed in the third lower insulating layer 330 of the third semiconductor chips 300 are exposed. The second gap filling portion 520 may be partially removed by a grinding process such as a chemical mechanical polishing (CMP) process. The third bonding pads 350 and the third lower insulating layer 330 of the third semiconductor chips 300 may be exposed from the second gap filling portion 520. Since the second gap filling portion 520 is partially removed until the third bonding pads 350 are sufficiently exposed from the second gap filling portion 520, failures such as a dishing phenomenon, an erosion phenomenon, etc. may be prevented from occurring in the third bonding pads 350.

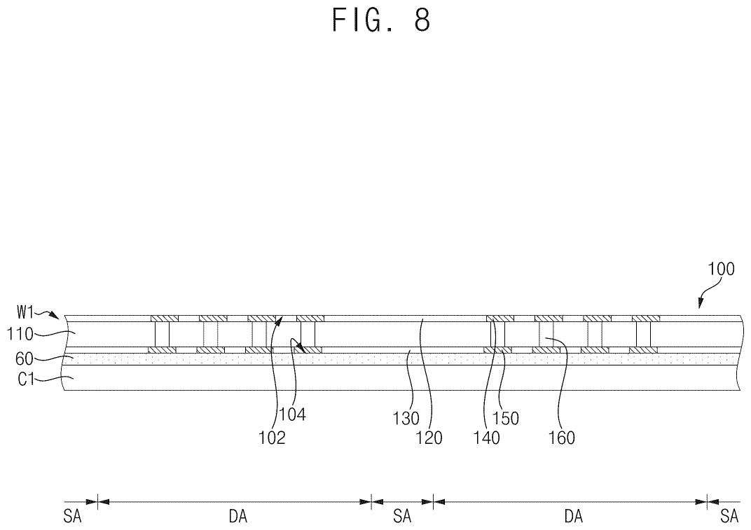

Referring to FIGS. 8 to 12, a first semiconductor wafer W1 may be provided and a plurality of second semiconductor chips 200 may be disposed on the first semiconductor wafer W1. The first semiconductor wafer W1 may be a base wafer for forming a first sub-package 32 (see FIG. 15).

As illustrated in FIG. 8, an adhesive member 60 may be formed on a first carrier substrate C1, and the first semiconductor wafer W1 having a plurality of first semiconductor chips 100 may be provided on the adhesive member 60.

In particular, the first semiconductor wafer W1 may be formed. A first activation layer having first bonding pads 150 may be formed on one surface of the first substrate 110, and first through electrodes 160 may be formed to penetrate at least a portion of the first substrate 110 and to be electrically connected to the first activation layer. A plurality of first conductive pads 140 may be formed on the first through electrodes 160, respectively, and a first upper insulating layer 120 may be formed on the first substrate 110 to expose the first conductive pads 140.

Then, the first semiconductor wafer W1 may be adhered to the adhesive member 60 that is formed on the first carrier substrate C1. The first semiconductor wafer W1 may be adhered to the adhesive member 60 such that the first activation layer of the first semiconductor wafer W1 faces the adhesive member 60.

The first semiconductor wafer W1 may include a die region DA in which the first semiconductor chip is disposed and a cutting region SA surrounding the die region DA. As will be described later, the first semiconductor wafer W1 may be cut along the cutting region SA through a sawing process to be individualized.

As illustrated in FIGS. 9 and 10, a plurality of second semiconductor chips 200 may be disposed on the first semiconductor wafer W1 (die-to-wafer hybrid bonding process). The second semiconductor chips 200 may be disposed on the first semiconductor wafer W1 such that second conductive pads 240 formed in a second upper insulating layer 220 of the second semiconductor chip 200 face the first semiconductor wafer W1. The plurality of second semiconductor chips 200 may be disposed on the first semiconductor wafer W1 by a reconstruction method.

The plurality of second semiconductor chips 200 may be fixed on the first semiconductor wafer W1 by a thermal compression process. The thermal compression process may be a technical process of stably bonding the plurality of second semiconductor chips 200 onto the first semiconductor wafer W1 using a high-temperature heat source.

The second lower insulating layer 230 of the second semiconductor chips 200 and the first upper insulating layer 120 of the first semiconductor wafer W1 may be directly bonded to each other. The second bonding pads 250 of the second semiconductor chips 200 may be bonded to the first conductive pads 140 of the first semiconductor wafer W1. Accordingly, the second bonding pads 250 and the first conductive pads 140 may be connected to each other between the second semiconductor chips 200 and the first semiconductor wafer W1 by Cu—Cu hybrid bonding. For example, pad to pad direct bonding may be formed.

The plurality of second semiconductor chips 200 may be disposed to be spaced apart from each other on the first semiconductor wafer W1. The plurality of second semiconductor chips 200 may be arranged to be spaced apart from each other by a first distance D1. In some embodiments, the first distance D1 between the plurality of second semiconductor chips 200 may be substantially the same as the second distance D2 between the plurality of third semiconductor chips 300.

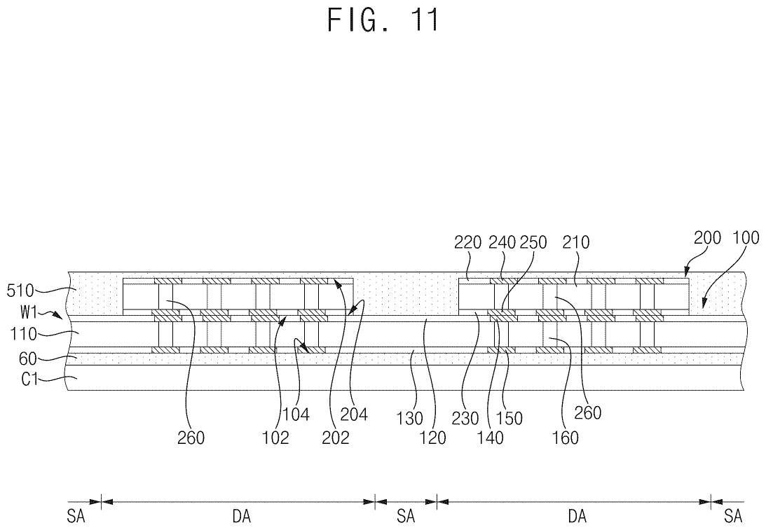

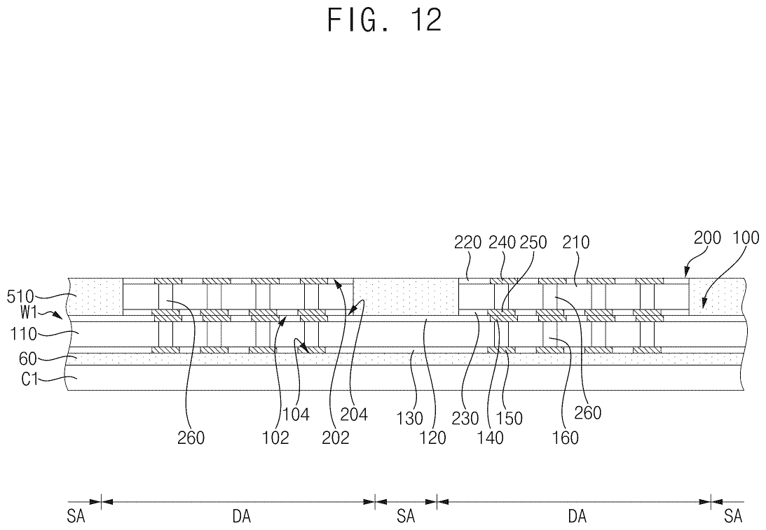

As illustrated in FIGS. 11 and 12, a first gap filling portion 510 may be formed on the first semiconductor wafer W1 to cover the plurality of second semiconductor chips 200. In example embodiments, the first gap filling portion 510 may be formed on the first semiconductor wafer W1 to cover the plurality of second semiconductor chips 200. For example, the first gap filling portion 510 may include an epoxy molding compound (EMC) or the like. Alternatively, the first gap filling portion 510 may include an inorganic dielectric layer or an organic dielectric layer. The inorganic dielectric layer may include silicon oxide, silicon oxynitride, phosphosilicate glass (PSG), boro-phosphosilicate glass (BPSG), etc. The organic dielectric layer may include a polymer or the like. The first gap filling portion 510 may be formed by a conformal deposition process such as an atomic layer deposition (ALD) process or a chemical vapor deposition (CVD) process.

Then, the first gap filling portion 510 may be polished using a substrate support system (WSS). The first gap filling portion 510 may be partially removed until the second conductive pads 240 formed in the second upper insulating layer 220 of the second semiconductor chips 200 are exposed. The first gap filling portion 510 may be partially removed by a grinding process such as a chemical mechanical polishing (CMP) process. The second conductive pads 240 and the second upper insulating layer 220 of the second semiconductor chips 200 may be exposed from the first molding member 510. Since the first molding member 510 is partially removed until the second conductive pads 240 are sufficiently exposed from the first molding member 510, failures such as a dishing phenomenon, an erosion phenomenon, etc. may be prevented from occurring in the second conductive pads 240.

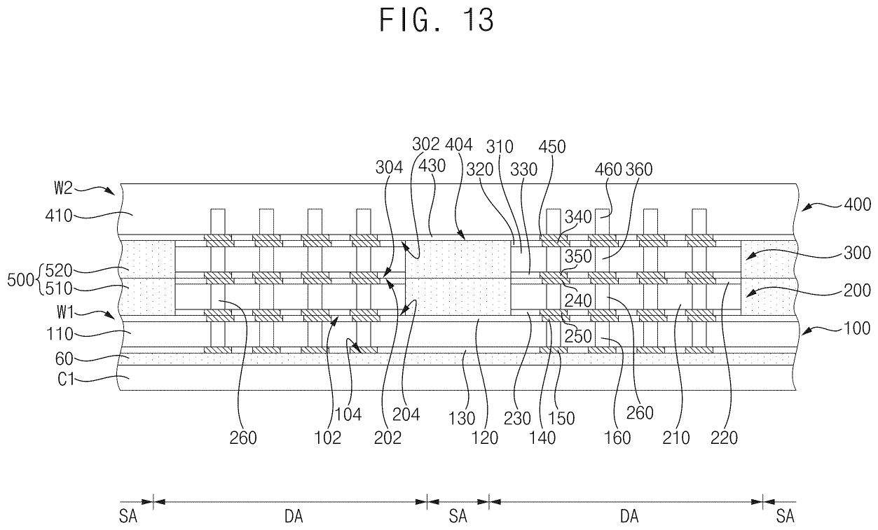

Referring to FIGS. 13 to 16, the third semiconductor chips 300 of the second semiconductor wafer W2 may be bonded onto the second semiconductor chips 200 of the first semiconductor wafer W1, and the fourth substrate 410 of the second semiconductor wafer W2 may be polished. Then, fourth conductive pads 440 and a fourth upper insulating layer 420 may be formed on the fourth substrate 410, and the first and second semiconductor wafers W1 and W2 may be cut to form an individual core die block 30.

As illustrated in FIG. 13, first, the structure in FIG. 7 may be turned over, the second gap filling portion 520 and the third semiconductor chips 300 may be attached onto the first gap filling portion 510 and the third semiconductor chips 300 respectively, and then, the second carrier substrate C2 may be removed from the fourth substrate 410.

The first and second semiconductor wafers W1 and W2 may be bonded such that the second semiconductor chips 200 of the first semiconductor wafer W1 and the third semiconductor chips 300 of the second semiconductor wafer W2 are bonded to each other. The first gap filling portion 510 of the first semiconductor wafer W1 and the second gap filling portion 520 of the second semiconductor wafer W2 may be bonded to each other. The first and second semiconductor wafers W1 and W2 may be bonded to each other by wafer-wafer direct bonding.

The second conductive pads 240 of the second semiconductor chips 200 may be bonded to the third bonding pads 350 of the third semiconductor chips 300, respectively. The second conductive pads 240 and the third bonding pads 350 may be electrically connected to each other. The second upper insulating layers 220 provided on the second upper surfaces 202 of the second semiconductor chips 200 and the third lower insulating layers 330 provided on the third lower surfaces 304 of the third semiconductor chips 300 may be directly bonded to each other. Accordingly, the second conductive pads 240 and the third bonding pads 350 may be bonded to each other between the first semiconductor wafer W1 and the second semiconductor wafer W2 by Cu—Cu hybrid bonding (pad to pad direct bonding).

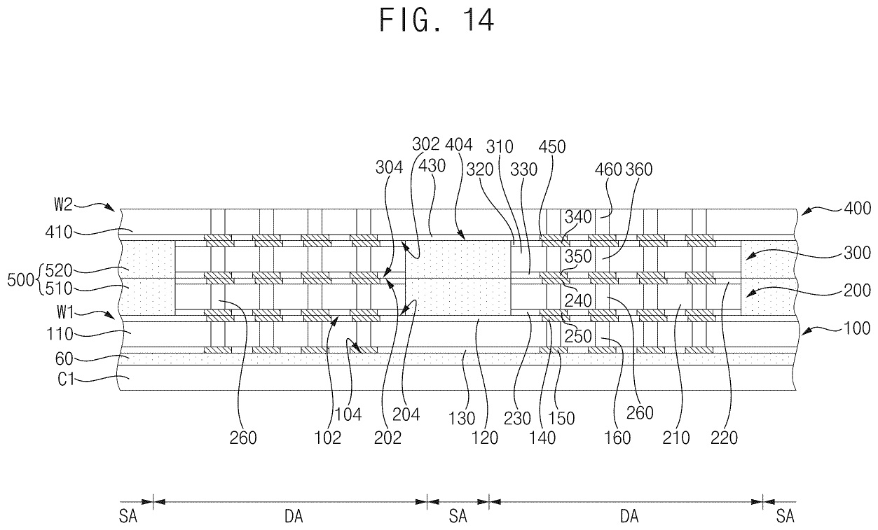

As illustrated in FIG. 14, a backside surface of the second semiconductor wafer W2 may be polished using a substrate support system WSS. The fourth substrate 410 may be partially removed until end portions of the fourth through electrodes 460 formed in the fourth substrate 410 are exposed. The backside surface of the fourth substrate 410 may be partially removed by a grinding process such as a chemical mechanical polishing (CMP) process. The fourth through electrodes 460 may be exposed from the fourth substrate 410. Since the fourth substrate 410 is partially removed until the fourth through electrodes 460 are sufficiently exposed from the fourth substrate 410, failures such a dishing phenomenon, an erosion phenomenon, etc. may be prevented from occurring in the fourth through electrodes 460.

As illustrated in FIG. 15, the fourth conductive pads 440 may be formed on the fourth through electrodes 460 that are exposed from the fourth substrate 410, respectively. The fourth upper insulating layer 420 may be formed on the fourth substrate 410 to expose the fourth conductive pads 440.

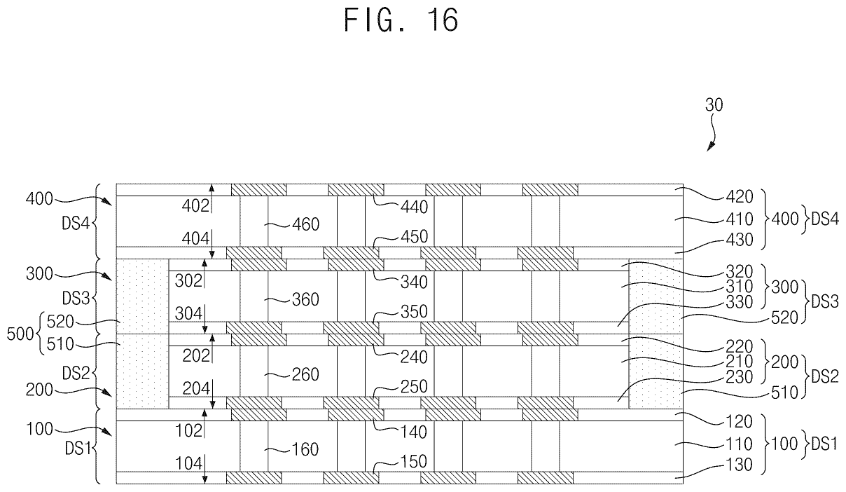

As illustrated in FIG. 16, the first and second semiconductor wafers W1 and W2 may be cut along the cutting region, that is, a scribe lane region SR to form individual core die blocks 30. The first and second semiconductor wafers W1 and W2 may be cut by a dicing process. The first and second semiconductor wafers W1 and W2 may be cut to complete the core die block 30 including a first sub-block and a second sub-block.

Each of the core die blocks 30 may include first, second, third and fourth die structures DS1, DS2, DS3, and DS4 sequentially stacked. The first die structure DS1 may include a first semiconductor chip 100. The second die structure DS2 may include a second semiconductor chip 200 and a first gap filling portion 510 that covers an outer side surface of the second semiconductor chip 200. The third die structure DS3 may include a third semiconductor chip 300 and a second gap filling portion 520 that covers an outer side surface of the third semiconductor chip 300. The fourth die structure DS4 may include a fourth semiconductor chip 400. In the embodiment illustrated in FIG. 16, the core die block 30 is illustrated as including the four stacked first, second, third and fourth semiconductor chips 100, 200, 300 and 400. However, embodiments are not limited thereto.

The core die block 30 may have a rectangular parallelepiped shape. A lower surface of the first die structure DS1 may serve as a lower surface of the core die block, and an upper surface of the fourth die structure DS4 may serve as an upper surface of the core die block.

When cutting the first and second semiconductor wafers W1 and W2, the first and second gap fill portions 510 and 520 of the stacked second and third die structures of the core die block 30 may be formed through a sawing process. Accordingly, outer side surfaces of the first and second gap filling portions 510 and 520 of the core die block 30 may be positioned on the same plane. In addition, the outer side surfaces of the first and second gap filling portions 510 and 520 of the core die block 30 may be coplanar with outer side surfaces of the first semiconductor chip 100 and the fourth semiconductor chip 400. When viewed in plan view, the first semiconductor chip 100 and the fourth semiconductor chip 400 may have the same size. When viewed in plan view, the second semiconductor chip 200 and the third semiconductor chip 300 may have smaller sizes than the first semiconductor chip 100 and the fourth semiconductor chip 400.

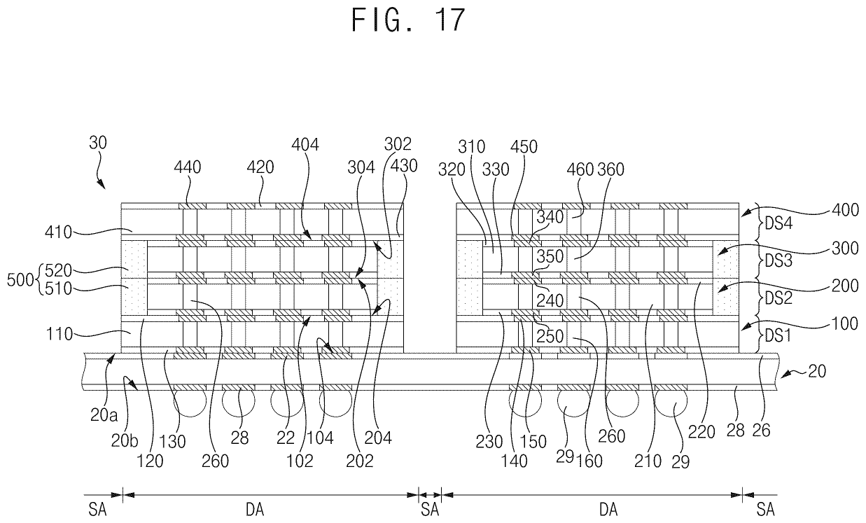

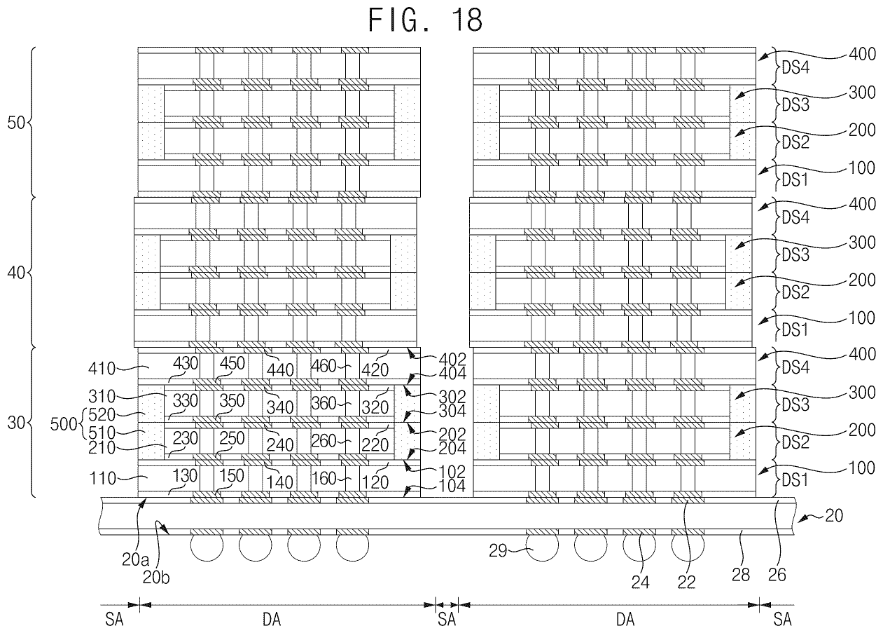

Referring to FIGS. 17 and 18, a plurality of core die blocks 30, 40, and 50 may be sequentially stacked on a buffer wafer including a buffer die 20. The plurality of core die blocks may include first to third core die blocks 30, 40, and 50.

As illustrated in FIG. 17, the first core die block 30 and the buffer die 20 may be directly bonded to each other. The first lower insulating layer 130 of the first core die block 30 and a first substrate insulating layer 26 of the buffer die 20 may be directly bonded to each other. Thus, the first bonding pads 150 and first substrate pads 22 may be bonded to each other between the first core die block 30 and the buffer die 20 by Cu—Cu Hybrid Bonding (pad to pad direct bonding).

As illustrated in FIG. 18, the first core die block 30 and the second core die block 40 may be directly bonded to each other, and the second core die block 40 and the third core die block 50 may be directly bonded to each other. Since each of the first to third core die blocks 30, 40, and 50 includes the first to fourth semiconductor chips 100, 200, 300, and 400, structural stability may be increased between the plurality of semiconductor chips stacked on each other.

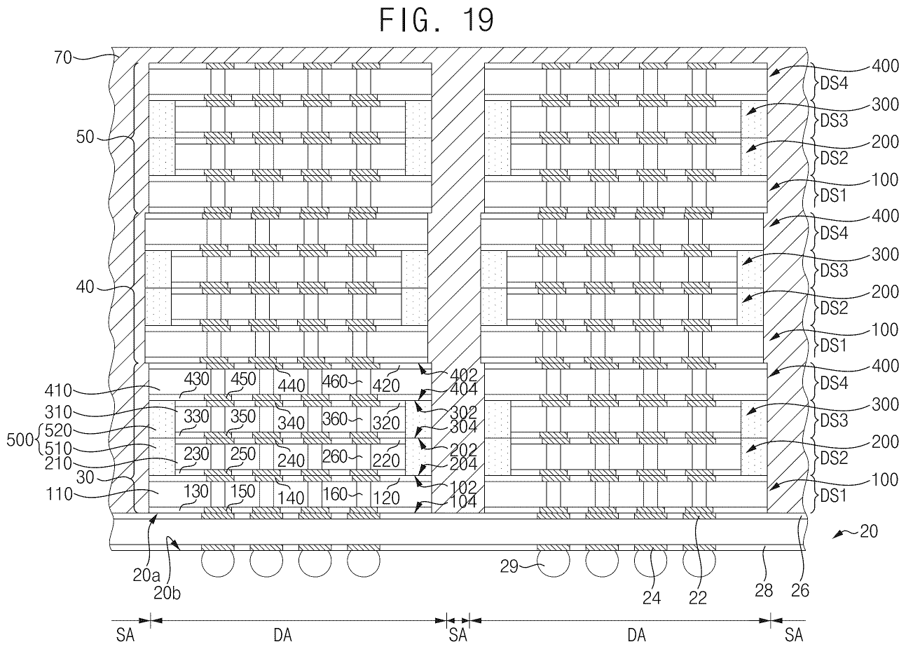

Referring to FIG. 19, a molding member 70 may be formed to fill gaps between the first, second, and third core die blocks 30, 40, and 50 sequentially stacked on the buffer wafer.

For example, the molding member 70 may be formed as a second gap filling portion between the first, second and third core die blocks 30, 40, 50 on the buffer wafer including the buffer die 20. The molding member 70 may cover an upper surface of the third core die block 50. The molding member 70 may be in direct contact with the outer side surfaces of the first, second, and third core die blocks 30, 40, and 50.

For example, the molding member may include a thermosetting resin. The molding material may include an epoxy mold compound (EMC). The molding material may include UV resin, polyurethane resin, silicone resin, silica filler, etc.

Then, the buffer wafer and a portion of the molding member 70 may be cut along a cutting region, that is, a scribe lane region SA, through a sawing process to form the semiconductor package 10 of FIG. 1.

As described above, in a process of manufacturing the semiconductor package 10, the plurality of second semiconductor chips 200 may be disposed on the first wafer including the first semiconductor chips 100 to form the first sub-package 32, and the plurality of third semiconductor chips 300 may be disposed on the second wafer including the fourth semiconductor chips 400 to form the second sub-package 34. The first and second sub-packages 32 and 34 may be bonded to each other to form the core die block.

Since the first and second sub-packages 32 and 34 are formed respectively by separate processes, the number of chip attaching times may be reduced compared to a case where a plurality of chips are individually stacked on the buffer die 20. Since the number of chip attaching times is reduced, chip alignment problems may be reduced. Since the first and second sub-packages 32 and 34 are formed respectively by separate processes, a warpage phenomenon occurring in a process of arranging thin chips may be prevented. Since the polishing process may be performed in the process of forming the first and second sub-packages 32 and 34, occurrence of a dishing phenomenon or an erosion phenomenon occurring in the first to third core die blocks 30, 40, and 50 may be reduced.

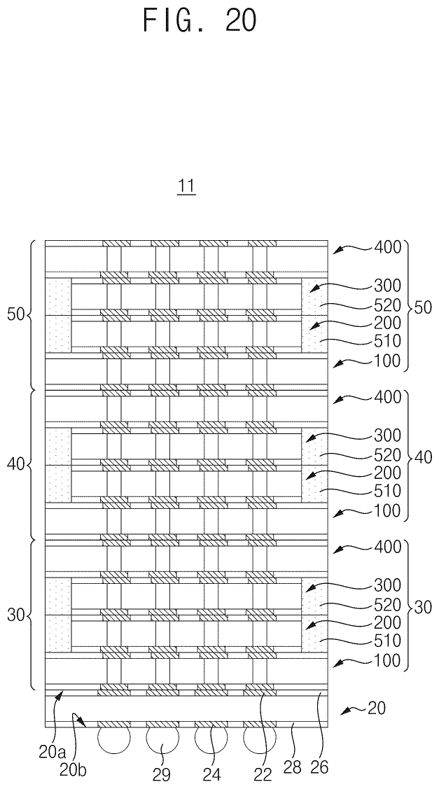

FIG. 20 is a cross-sectional view illustrating a semiconductor package in accordance with some example embodiments. The semiconductor package is substantially the same as the semiconductor package described with reference to FIGS. 1 and 2 except that a molding member is omitted. Thus, same reference numerals may be used to refer to the same or like elements and any further repetitive explanation concerning the above elements will be omitted.

Referring to FIG. 20, a semiconductor package 11 may include a buffer die 20, and a plurality of core die blocks stacked on the buffer die 20. The plurality of core die blocks may include a first core die block 30, a second core die block 40, and a third core die block 50. The first to third core die blocks 30, 40, and 50 may be sequentially stacked on the buffer die 20. The first to third core die blocks 30, 40, and 50 may be sequentially the same as or similar to the core die blocks 30, 40, and 50 of FIG. 1. Thus, same or similar elements are denoted by the same or similar reference numerals, and repeated descriptions of the same components will be omitted for conciseness.

In example embodiments, outer side surfaces of the first to third core die blocks 30, 40, and 50 may be located on the same plane. Additionally, the outer side surfaces of the first to third core die blocks 30, 40, and 50 may be located on the same plane as an outer side surface of the buffer die 20. Each of planar areas of the first to third core die blocks 30, 40, and 50 may be the same as a planar area of the buffer die 20.

Hereinafter, a method of manufacturing the semiconductor package of FIG. 20 will be described.

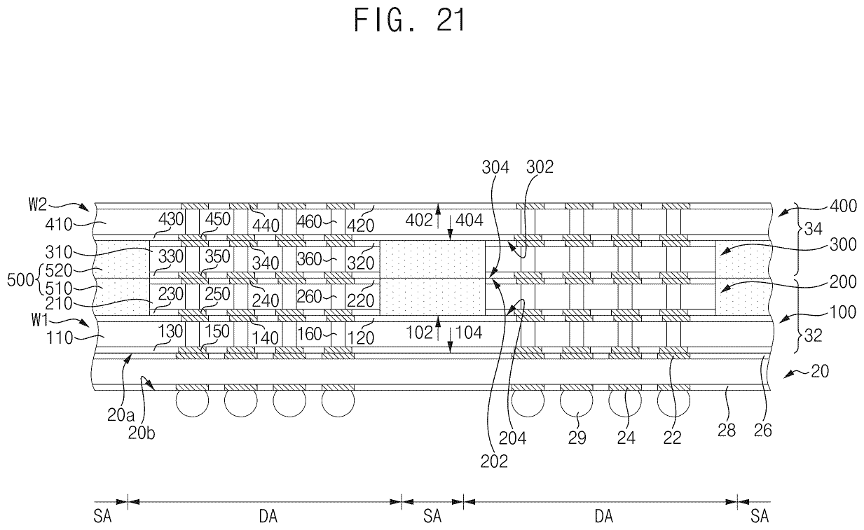

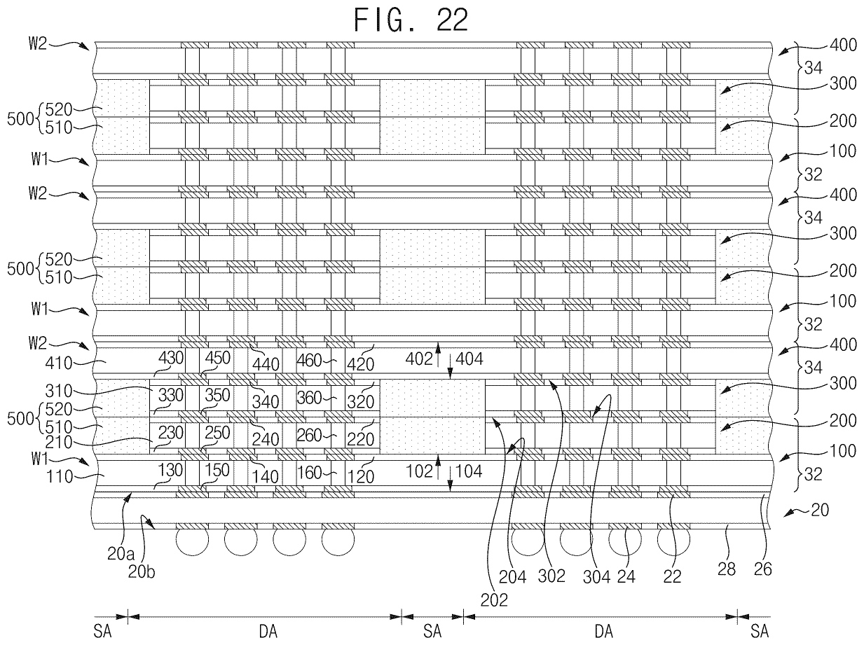

FIGS. 21 and 22 are cross-sectional views illustrating a method of manufacturing a semiconductor package in accordance with example embodiments.

Referring to FIG. 21, processes the same as or similar to the processes described with reference to FIGS. 3 to 15 may be performed to bond third semiconductor chips 300 on a second semiconductor wafer W2 onto second semiconductor chips 200 on a first semiconductor wafer W1 respectively to form a core die stack structure including a first sub-package 32 and a second sub-package 34 stacked on each other, and the core die stack structure may be stacked on a buffer wafer including a buffer die 20.

The core die stack structure as a first core die stack structure and the buffer wafer including the buffer die 20 may be bonded to each other by wafer-wafer direct bonding. A first lower insulating layer 130 of the first semiconductor chip 100 of the first core die stack structure and a first substrate insulating layer 26 of the buffer die 20 may be directly bonded to each other. Accordingly, first bonding pads 150 and first substrate pads 22 may be bonded to each other between the first semiconductor chip 100 of the first core die stack structure and the buffer die 20 by Cu—Cu hybrid bonding (pad-to-pad direct bonding).

Referring to FIG. 22, the core die stack structures of FIG. 15 in which the first sub-package 32 and the second sub-package 34 are stacked on each other may be sequentially stacked on the first core die stack structure.

First, the core die stack structure as a second core die stack structure may be stacked on the first core die stack structure. The second core die stacked structure and the first core die stack structure may be bonded to each other by wafer-wafer direct bonding. A first lower insulating layer 130 of a first semiconductor chip 100 of the second core die stack structure and a fourth upper insulating layer 420 of a fourth semiconductor chip 400 of the first core die stack structure are directly bonded to each other.

Similarly, the core die stack structure as a third core die stack structure may be stacked on the second core die stack structure. The third core die stack structure and the second core die stacked structure may be bonded to each other by wafer-wafer direct bonding. A first lower insulating film 130 of a first semiconductor chip 100 of the third core die stacked structure and a fourth upper insulating layer 420 of a fourth semiconductor chip 400 of the second core die stacked structure are directly bonded to each other.

Then, the buffer wafer and portions of the first to third core die stack structures may be cut along a cutting region, that is, a scribe lane region SA, through a sawing process to form the semiconductor package 11 of FIG. 20. The portions of the first to third core die stack structures may be cut by the sawing process, to form first to third core die blocks (30, 40, and 50, see FIG. 20) that are individually separated and sequentially stacked. Accordingly, outer side surfaces of the first to third core die blocks may be located on the same plane. Additionally, outer side surfaces of the first to third core die blocks may be located on the same plane as an outer side surface of the buffer die 20.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present disclosure. Accordingly, all such modifications are intended to be included within the scope of example embodiments as defined in the claims.

What is claimed is:

1. A semiconductor package comprising:
a buffer die;
a plurality of core die blocks sequentially stacked on the buffer die; and
a molding member on the buffer die and covering outer surfaces of the plurality of core die blocks,
wherein each of the core die blocks includes:
a first semiconductor chip having a plurality of first conductive pads that are exposed from a first upper surface of the first semiconductor chip and a plurality of first bonding pads that are exposed from a first lower surface of the first semiconductor chip;
a second semiconductor chip and a first gap filling portion covering an outer side surface of the second semiconductor chip, the second semiconductor chip having a plurality of second conductive pads that are exposed from a second upper surface of the second semiconductor chip and a plurality of second bonding pads that are exposed from a second lower surface of the second semiconductor chip, the plurality of second bonding pads of the second semiconductor chip being bonded to the plurality of first conductive pads of the first semiconductor chip;
a third semiconductor chip and a second gap filling portion covering an outer side surface of the third semiconductor chip, the third semiconductor chip having a plurality of third conductive pads that are exposed from a third upper surface of the third semiconductor chip and a plurality of third bonding pads that are exposed from a third lower surface of the third semiconductor chip, the plurality of third bonding pads of the plurality of third semiconductor chips being bonded to the plurality of second conductive pads of the second semiconductor chip; and
a fourth semiconductor chip having a plurality of fourth bonding pads that are exposed from a fourth lower surface of the fourth semiconductor chip that is opposite to a fourth upper surface of the fourth semiconductor chip, the plurality of fourth bonding pads being bonded to the plurality of third conductive pads of the third semiconductor chip.

2. The semiconductor package of claim 1, wherein an outer side surface of the second gap filling portion is located on the same plane as an outer side surface of the first gap filing portion.

3. The semiconductor package of claim 1, wherein the outer side surfaces of the first and second gap filling portions are located on the same plane as an outer side surface of the first semiconductor chip and an outer side surface of the fourth semiconductor chip.

4. The semiconductor package of claim 1, wherein a first planar area of the first semiconductor chip is equal to a fourth planar area of the fourth semiconductor chip.

5. The semiconductor package of claim 4, wherein a second planar area of the second semiconductor chip is smaller than the first planar area of the first semiconductor chip, and a third planar area of the third semiconductor chip is smaller than the first planar area of the first semiconductor chip.

6. The semiconductor package of claim 1, wherein the fourth semiconductor chip further includes a plurality of fourth conductive pads that are exposed from the fourth upper surface, and
wherein the plurality of fourth conductive pads of a first core die block of the plurality of core die blocks are bonded to a plurality of first bonding pads of a second core die block of the plurality of core die blocks.

7. The semiconductor package of claim 1, wherein the first semiconductor chip includes a plurality of first through electrodes that electrically connect the plurality of first conductive pads and the plurality of first bonding pads,
each of the plurality of second semiconductor chips includes a plurality of second through electrodes that electrically connect the plurality of second conductive pads and the plurality of second bonding pads, and
each of the plurality of third semiconductor chips includes a plurality of third through electrodes that electrically connect the plurality of third conductive pads and the plurality of third bonding pads.

8. The semiconductor package of claim 1, wherein a height from the first lower surface of the first semiconductor chip to the fourth upper surface of the fourth semiconductor chip is within a range of 100 μm to 200 μm.

9. The semiconductor package of claim 1, further comprising:
a plurality of external connection bumps respectively provided on a plurality of second substrate pads that are exposed from a lower surface of the buffer die.

10. The semiconductor package of claim 1, wherein the first to third conductive pads and the first to fourth bonding pads include at least one of Copper (Cu), Aluminum (Al), Tungsten (W), Nickel (Ni), Molybdenum (Mo), Gold (Au), Silver (Ag), Chromium (Cr), Tin (Sn), and Titanium (Ti).

11. A semiconductor package comprising:
a buffer die having a first surface and a second surface opposite to the first surface, the buffer die having a plurality of substrate pads that are exposed from the first surface; and
a plurality of core die blocks sequentially stacked on the first surface of the buffer die,
wherein each of the plurality of core die blocks includes:
a first semiconductor chip having a plurality of first conductive pads that are exposed from a first upper surface of the first semiconductor chip and a plurality of first bonding pads that are exposed from a first lower surface of the first semiconductor chip;
a second semiconductor chip and a first gap filling portion covering an outer side surface of the second semiconductor chip, the second semiconductor chip having a plurality of second conductive pads that are exposed from a second upper surface of the second semiconductor chip and a plurality of second bonding pads that are exposed from a second lower surface of the second semiconductor chip, the plurality of second bonding pads of the second semiconductor chip being bonded to the plurality of first conductive pads;
a third semiconductor chip and a second gap filling portion covering an outer side surface of the third semiconductor chip, the third semiconductor chip having a plurality of third conductive pads that are exposed from a third upper surface of the third semiconductor chip and a plurality of third bonding pads that are exposed from a third lower surface of the third semiconductor chip, the plurality of third bonding pads of the third semiconductor chip being bonded to the plurality of second conductive pads of the second semiconductor chip; and
a fourth semiconductor chip having a plurality of fourth conductive pads that are exposed from a fourth upper surface of the fourth semiconductor chip and a plurality of fourth bonding pads that are exposed from a fourth lower surface of the fourth semiconductor chip, the plurality of fourth bonding pads being bonded to the plurality of third conductive pads of the third semiconductor chip, and
wherein the plurality of first bonding pads of a lowermost core die block among the plurality of core die blocks are bonded to the plurality of substrate pads of the buffer die.

12. The semiconductor package of claim 11, wherein an outer side surface of the second gap filling portion is located on the same plane as an outer side surface of the first gap filing portion.

13. The semiconductor package of claim 11, wherein the outer side surfaces of the first and second gap filling portions are located on the same plane as an outer side surface of the first semiconductor chip and an outer side surface of the fourth semiconductor chip.

14. The semiconductor package of claim 11, wherein a first planar area of the first semiconductor chip is equal to a fourth planar area of the fourth semiconductor chip.

15. The semiconductor package of claim 14, wherein a second planar area of the second semiconductor chip is smaller than the first planar area of the first semiconductor chip, and a third planar area of the third semiconductor chip is smaller than the first planar area of the first semiconductor chip.

16. The semiconductor package of claim 11, wherein the first semiconductor chip includes a plurality of first through electrodes that electrically connect the plurality of first conductive pads and the plurality of first bonding pads,
each of the plurality of second semiconductor chips includes a plurality of second through electrodes that electrically connect the plurality of second conductive pads and the plurality of second bonding pads, and
each of the plurality of third semiconductor chips includes a plurality of third through electrodes that electrically connect the plurality of third conductive pads and the plurality of third bonding pads.

17. The semiconductor package of claim 11, wherein a height from the first lower surface of the first semiconductor chip to the fourth upper surface of the fourth semiconductor chip is within a range of 100 μm to 200 μm.

18. The semiconductor package of claim 11, wherein the buffer die includes:
a plurality of second substrate pads exposed from the second surface of the buffer die; and
a plurality of external connection bumps provided on the plurality of second substrate pads, respectively.

19. The semiconductor package of claim 11, wherein the first to fourth conductive pads and the first to fourth bonding pads include at least one of Copper (Cu), Aluminum (Al), Tungsten (W), Nickel (Ni), Molybdenum (Mo), Gold (Au), Silver (Ag), Chromium (Cr), Tin (Sn), and Titanium (Ti).

20. A semiconductor package comprising:
a buffer die having a first surface and a second surface opposite to the first surface;
a plurality of core die blocks sequentially stacked on the first surface of the buffer die; and
a molding member on the first surface of the buffer die covering outer surfaces of the plurality of the core die blocks,
wherein each of the core die blocks includes:
a first semiconductor chip having a first upper surface and a first lower surface opposite to the first upper surface, the first semiconductor chip having a plurality of first conductive pads that are exposed from the first upper surface and a plurality of first bonding pads that are exposed from the first lower surface;
a second semiconductor chip and a first gap filling portion covering an outer side surface of the second semiconductor chip, the second semiconductor chip having a second upper surface and second lower surface opposite to the second upper surface, a plurality of second conductive pads that are exposed from the second upper surface and a plurality of second bonding pads that are exposed from the second lower surface, the plurality of second bonding pads of the second semiconductor chip being bonded to the plurality of first conductive pads;
a third semiconductor chip and a second gap filling portion covering an outer side surface of the third semiconductor chip, the third semiconductor chip having a third upper surface and a third lower surface opposite to the third upper surface, a plurality of third conductive pads that are exposed from the third upper surface and a plurality of third bonding pads that are exposed from the third lower surface, the plurality of third bonding pads of the third semiconductor chip being bonded to the plurality of second conductive pads of the of second semiconductor chips; and
a fourth semiconductor chip having a fourth upper surface and a fourth lower surface opposite to the fourth upper surface, the fourth semiconductor chip having a plurality of fourth conductive pads that are exposed from the fourth upper surface and a plurality of fourth bonding pads that are exposed from the fourth lower surface, the plurality of fourth bonding pads being bonded to the plurality of third conductive pads of the third semiconductor chip,
wherein the first gap filling portion and the second gap filling portion contact each other.
